(19) United States
(12) Patent Application Publication
(10) Pub. No.: US 2015/0274197 A1
(43) Pub. Date: Oct. 1, 2015

(54) ELECTRONIC CONTROLLER FOR ELECTRIC POWER STEERING

(71) Applicant: NIDEC ELESYS CORPORATION, Kawasaki-shi (JP)

(72) Inventors: Tsuneyuki SAITO, Kawasaki-shi (JP); Jun KATSUMATA, Kawasaki-shi (JP)

(21) Appl. No.: 14/669,440

(22) Filed: Mar. 26, 2015

(30) Foreign Application Priority Data
Mar. 27, 2014 (JP) 2014-066056
Mar. 6, 2015 (JP) 2015-044659

(51) Int. Cl. B62D 5/04; H02P 27/06; H05K 1/14; H02P 6/14; H05K 7/20; H05K 5/00

(52) U.S. Cl. CPC B62D 5/0406; H05K 7/2039; H05K 5/0026; H05K 1/144; H02P 6/14; H02P 27/06

(57) ABSTRACT

An electronic controller for electric power steering includes a first board, a second board, an insert molded component, a heat sink, and a protective cover. First surface-mounted components are mounted on the first board. Second surface-mounted components having a higher tolerant current capacity than that of the first surface-mounted components are mounted on the second board. The insert molded component includes connectors mounted at a first end portion of the second board and mounted at a second end portion located vertically to the first end portion. The heat sink externally radiates heat transferred from the second surface-mounted component to the second board. The protective cover is fixed to the heat sink to cover the first board and the second board on which the insert molded component is mounted.

### BACKGROUND OF THE INVENTION

1. Field of the Invention

The present invention relates to an electronic controller for electric power steering.

2. Description of the Related Art

Recently, development of electric power steering (referred to as EPS, hereinafter) systems has been encouraged for the purpose of reducing drivers' load on vehicle driving. An EPS system is a system to assist a steering torque generated by a steering wheel using an auxiliary torque generated by a multiphase brushless motor, and is controlled by an electronic control unit (referred to as ECU, hereinafter).

Such an ECU includes a power circuit that controls the multiphase brushless motor of the EPS, and a control circuit that controls this motor. The power circuit includes an insert molded board, and multiple power boards. The control circuit includes a control board. The insert molded board is a board formed in such a manner that DIP (dual inline package) components including a coil for noise reduction, a power source relay, a failsafe relay, and others are connected to an insert molded article in which a bus bar is insert-molded, through soldering, welding or the like. The power board is an aluminum board on which semiconductor switching elements surface-mounted to supply large current for the multiphase brushless motor, and shunt resistors for current detection and others are mounted. The control board is a glass epoxy board where a control microcomputer, a drive circuit for driving the semiconductor switching elements, amplifier circuits for various sensors externally connected, and others are mounted. The ECU has a structure in which the insert molded board, the multiple power boards, and the control board are connected through soldering, welding, or the like, and are covered with a cover member. The ECU generates torque by supplying large current for the multiphase brushless motor, thus assisting driver's steering on a steering wheel.

In the above described ECU, there has been known such a conventional mounting structure of an ECU for EPS that mounts relatively tall components, such as a bridge circuit including semiconductor switching elements connected to respective phases, a smoothening electrolytic capacitor, relays for realizing failsafe, a coil for noise removal, and others, on a power board (Japanese Patent Laid-Open No. 2004-17884, for example). This structure simplifies the manufacturing process, and attains downsizing and reduction in thickness.

According to a technique disclosed in Japanese Patent Laid-Open No. 2004-17884, in a case that houses the control board and the power board, a connecting portion used for electrically connecting the control board and the power board is located at a center of the case. Specifically, there is provided a connecting member for connecting respective pairs of two sides of the control board and the power board that face each other at the center, and this connecting member and the case are integrally molded. The inside of the case is partitioned into two sections by this connecting member, the power board is disposed in one section, and the control board is disposed in the other section so that electronic components installed on the control board are prevented from overlapping relatively tall electronic components installed on the power board, thus attaining reduction in thickness.

In the aforementioned ECU for EPS, the dimension in the height direction of the unit is determined depending on the dimension of the electronic components included in the power circuit. In the insert molded board, its circuit is formed of connectors and a bus bar, and thus the insert molded board becomes greater than the control board that includes the control circuit and part of the power circuits. Electronic components mounted in an electronic controller for electric power steering include both surface-mounted components and DIP components. Consequently, a soldering process is required in addition to a surface-mounting process, which increases the number of connecting processes and becomes a factor of increase in manufacturing cost.

Furthermore, in column-assist type EPS, an ECU is disposed in the vicinity of a multiphase brushless motor. In this area where the motor is disposed, other components of a vehicle are closely arranged, and if the design of the vehicle is changed, the arrangement of these components is also changed; therefore, an outer shape applied to the ECU is required to be changed. In this case, every time the design of the vehicle is changed, the entire insert molded board is also required to be changed, resulting in increase in manufacturing cost.

### SUMMARY OF THE INVENTION

According to one exemplary preferred embodiment of the present invention, an electronic controller for electric power steering includes a first board, a second board, an insert molded component, a heat sink, and a protective cover. First surface-mounted components are mounted on the first board. Second surface-mounted components having a higher tolerant current capacity than that of the first surface-mounted components are mounted on the second board. The insert molded component includes connectors mounted at a first end portion of the second board and mounted at a second end portion vertical to the first end portion. The heat sink externally radiates heat transferred from the second surface-mounted components to the second board. The protective cover is fixed to the heat sink to cover the first board and the second board on which the insert molded component is mounted.

According to one exemplary preferred embodiment of the present application, it is possible to provide an electronic controller for electric power steering capable of attaining further downsizing, low cost, and enhanced usability.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a drawing showing an example of an appearance configuration of an electronic controller for electric power steering according to a preferred embodiment of the present invention.

FIG. 2 is an exploded perspective view of the electronic controller for electric power steering of FIG. 1;

FIG. 3 is a drawing showing shapes of connectors mounted on the electronic controller for electric power steering of FIG. 1.

FIG. 4 is a perspective view showing a component mounting structure of the electronic controller for electric power steering of FIG. 1.

FIG. 5 is a drawing showing another example of the appearance configuration of the electronic controller for electric power steering according to a preferred embodiment of the present invention.

FIG. 6 is a plan view of electronic components mounted on a control board included in the electronic controller for electric power steering according to a preferred embodiment of the present invention.

FIG. 7 is a plan view of electronic components mounted on a power board included in the electronic controller for electric power steering according to a preferred embodiment of the present invention.

FIG. 8 is an electric circuit diagram of the electronic controller for electric power steering according to a preferred embodiment of the present invention.

FIG. 9 is a drawing showing a schematic structure of mechanical portions of an electric power steering system including the electronic controller for electric power steering according to a preferred embodiment of the present invention.

### DETAILED DESCRIPTION OF THE PREFERRED EMBODIMENTS

Hereinafter, an electronic controller (e.g., an ECU) for electric power steering (simply referred to as an 1A:ECU or 1B:ECU, hereinafter) according to preferred embodiments of the present invention (simply referred to as present preferred embodiments, hereinafter) will be described in detail.

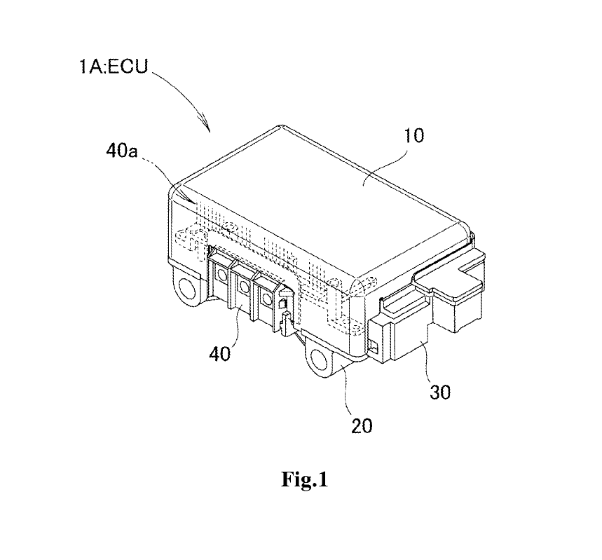

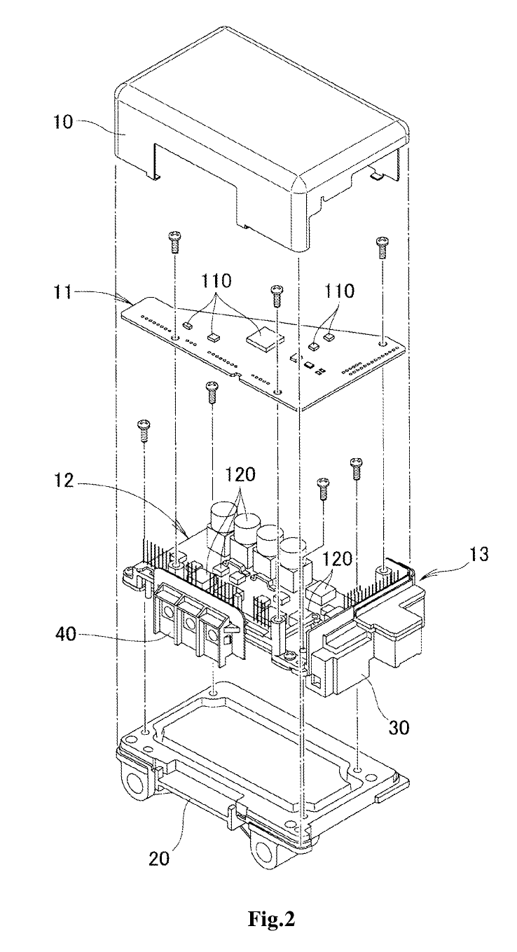

As shown in FIG. 1, the 1A:ECU according to the present preferred embodiment has a stacked structure that holds boards (for example, control board 11 and power board 12 in FIG. 2 described later) on which not-shown electronic components are mounted between a protective cover 10 and a heat sink 20. In this structure, a terminal base 40 configured to be connected to an externally connectable three-phase brushless motor is preferably disposed at a slit in a longitudinal side wall of the protective cover 10, and an externally connectable connector 30 configured to be connected to a power source system and vehicle sensors is preferably disposed at a cutout in another side wall vertical to the above longitudinal side wall. The protective cover 10 may also be configured to electromagnetically shield the control board 11 and the power board 12 that are stacked.

As shown in its exploded perspective view of FIG. 2, the 1A:ECU according to the present preferred embodiment includes a board-mounting structure that stacks the control board 11 (first board) on which surface-mounted control components 110 (first surface-mounted components) included in a control circuit are mounted, and the power board 12 (second board) on which surface-mounted power components 120 (second surface-mounted components) included in a drive circuit for a multiphase brushless motor with a greater tolerable current capacity than that of the surface-mounted control components 110 are mounted. Characteristically, an insert molded component 13 including connectors is directly mounted at end portions of the power board 12, and the insert molded component 13 is provided in an L shape and located at a first portion that is an end portion in the longitudinal direction of the power board 12, and also at a second portion that is another end portion vertical to the first portion. The insert molded component 13 is preferably formed of electrically insulating resin, for example.

The control board 11 is preferably fixed at its end portions to the insert molded component 13 with three screws, for example, and the power board 12 is preferably fixed at its end portions to the heat sink 20 with four screws, for example.

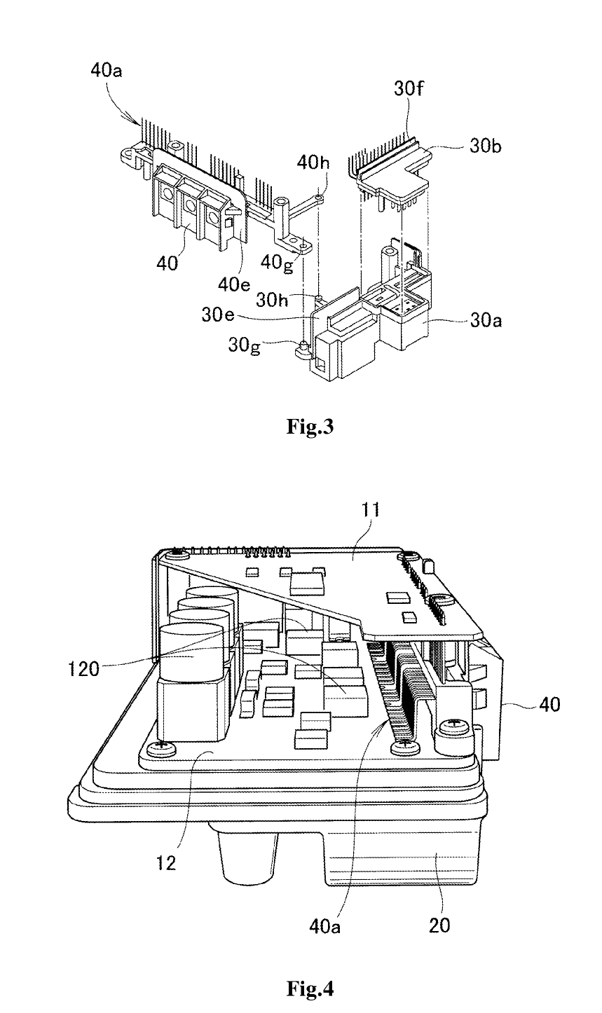

The insert molded component 13, as shown in FIG. 3 for example, preferably includes: a power source connecting connector 30a (second connector) to which a vehicle power source is connected; the second portion that is the externally connectable connector 30 including a signal connecting connector 30b (third connector) to which vehicle sensors, such as, for example, a torque sensor (70 in FIGS. 8 & 9) and an angle sensor (90 in FIGS. 8 & 9), which will be described later, are connected; and the first portion that is a motor connecting connector 40 (first connector) to which the three-phase brushless motor 50 is connected. The motor connecting connector is mounted at a first end portion of the longitudinal end portion of the power board 12, and the externally connectable connector 30 is mounted at a second end portion in the other direction than the longitudinal end portion. Coupling portions (40g & 40h) of the motor connecting connector 40 and coupling portions (30g & 30h) of the externally connectable connector 30 are preferably integrally formed by being coupled with each other through press-fitting or welding, for example. Through this structure, in the case of changing the mounting position of the 1A:ECU, of the insert molded component 13, only a portion affected by influences due to this change needs to be remade, thus reducing cost required for changing the mold, thus attaining reduction in cost for the 1A:ECU.

For example, as shown in FIG. 3, the motor connecting connector 40 (first connector) preferably includes: a first wall portion 40e in contact with an inside portion of the slit in the longitudinal side wall of the protective cover 10; the power source connecting connector 30a (second connector) to which the vehicle power source is connected preferably includes a second wall portion 30e in contact with an inside portion of the cutout in a side wall vertical to the longitudinal direction of the protective cover 10; and the signal connecting connector 30b (third connector) to which the vehicle sensors are connected preferably includes a third wall portion 30f in contact with another inside portion of the cutout in the side wall vertical to the longitudinal direction of the protective cover 10. This structure allows the 1A:ECU to seal a gap between the protective cover 10 and the insert molded component 13, so that enhanced dust proof is achieved.

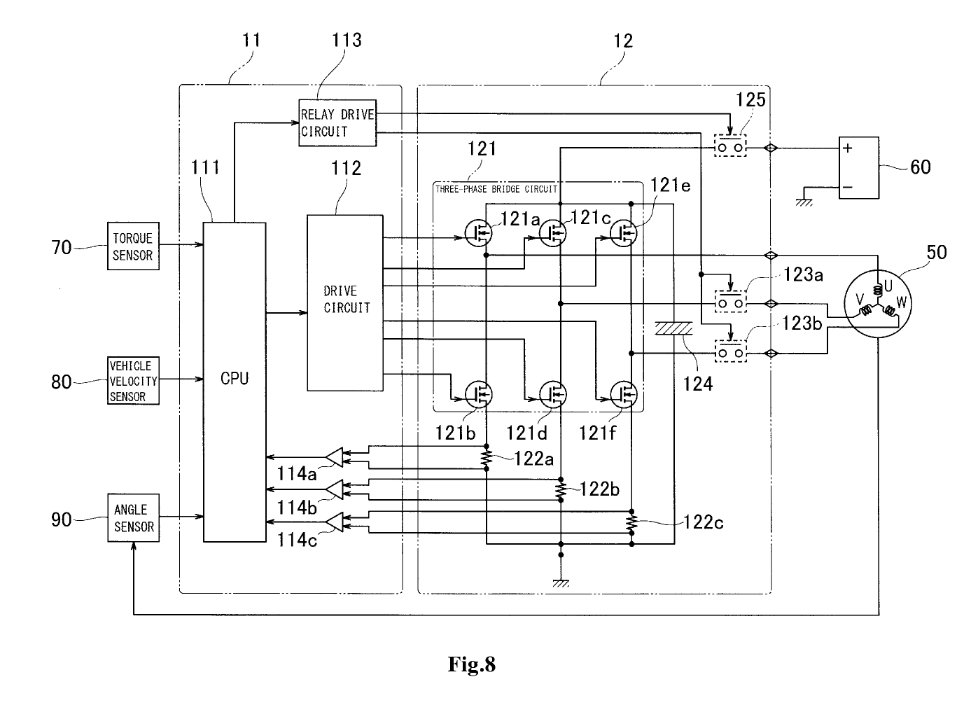

For example, as shown in FIG. 4, the insert molded component 13 is mounted in line along the longitudinal end portion of the power board 12, and includes a terminal block 40a that connects the surface-mounted control components 110 mounted on the control board 11 to the surface-mounted power components 120 mounted on the power board 12. This terminal block 40a is preferably connected to a terminal block 120a (FIG. 7) arranged in line to oppose the end portion of the power board 12. Accordingly, it is possible to eliminate wiring to the connectors located apart because of limitation of the mounting arrangement of the components, thus simplifying the wiring layout, and enhancing flexibility in designing of wiring. The control board 11 is preferably mounted on the insert molded component 13 in an L shape including the connectors mounted at the end portions of the power board 12; therefore, the control board 11 is configured to include a cutout end portion which is not fixed on the insert molded component 13, thus improving seismic resistance. The board area of the control board 11 becomes decreased, so that increase in number of boards is efficiently improved, resulting in cost reduction.

As described above, it is possible to attain efficient layout without deviation of the electronic components, thus downsizing the entire 1A:ECU, and all the surface-mounted power components 120 are mounted on the single power board 12, which eliminates redundant wiring. All the electronic components required as the 1A:ECU are also surface-mounted on the power board 12 so as to attain reduction in thickness, and all of these electronic components are allowed to be connectable by reflow soldering, thus simplifying the assembly process, resulting in cost reduction.

The “surface-mounted components” herein denote electronic components for a surface mount technology (SMT), and provide advantages including a smaller mounting space compared with a through-hole technology that fixes leads of the electronic components to holes in a printed wiring board. Basically, after soldering printing onto the board by using a cream solder printing machine, or application of adhesive onto the component installation positions by using a dispenser, the components are mounted by using a chip mounter, and thereafter, the solder is melted with heat in a reflow oven to fix the electronic components to the board. A “tolerant current capacity” denotes a maximum current to be supplied for standard electronic components. An electronic component has electric resistance, and if voltage is applied to the electronic component to supply current therefor, the electronic component generates heat due to its electric resistance. If this heat melts an insulating film covering the electronic component, a short circuit is caused, or a fire is started. Therefore, a tolerant current capacity is specified for each electronic component in order to prevent such troubles.

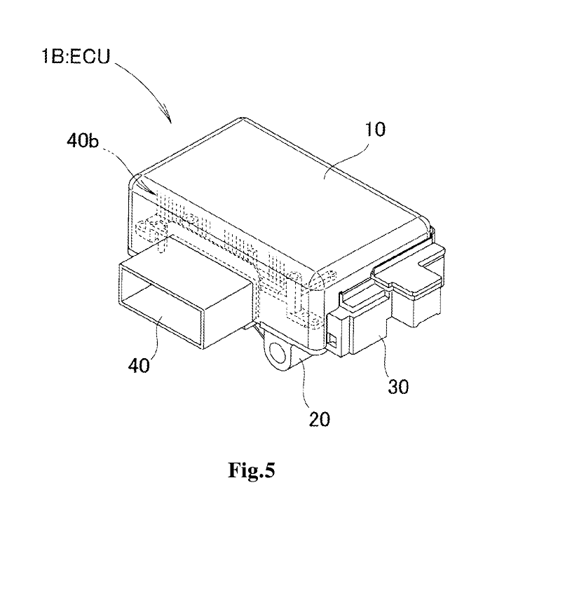

EPS may be chiefly classified into a column assist type, a pinion assist type, and a rack assist type depending on the place where power assistance is carried out by using a motor. The column assist type is directed to a system which provides turning assistance a steering column that connects a steering wheel and a gear box by using a driving force of a motor, and an ECU is usually disposed in the vicinity of the motor. Herein, an ECU of this type is referred to as a close-arranged 1A:ECU, and an ECU of the other types is referred as a standalone 1B:ECU. The 1A:ECU preferably has the structure shown in FIG. 1, and the 1B:ECU preferably has the structure and a connector shape shown in FIG. 5. In the standalone 1B:ECU, the motor connecting connector 40 configured to connect to the three-phase brushless motor is preferably disposed to project out from the slit in the longitudinal side wall of the protective cover 10, and the externally connectable connector 30 configured to connect to the power source system and the vehicle sensors is disposed at the cutout in another side wall vertical to this longitudinal side wall. The externally connectable connector 30 and the motor connecting connector 40 are preferably integrally formed by being coupled with each other at respective coupling portions through press-fitting or welding.

Some close-arranged ECUs are frequently required to be able to change an arrangement of the connectors depending the vehicle layout, and this causes a change of the whole insert molded component formed by integrally molding the connectors and the bus bar in accordance with the vehicle type, resulting in increase in manufacturing cost. To the contrary, in the 1A:ECU according to the present preferred embodiment, at the longitudinal end portion of the insert molded component 13, the motor connecting connector 40 having, for example, either a terminal base shape (first shape) or a connector shape (second shape) to be determined depending on the layout of the vehicle is selectively mounted. Specifically, depending on the layout of the vehicle, the insert molded component 13 integrally formed in an L shape may be partially remade in such a manner that molded components having a terminal base shape are replaced with molded components having a connector shape, for example. In other words, in order to remake the insert molded component 13 integrally formed in an L shape, it is only necessary to change the mold for connection to the motor; therefore, it is possible to reduce manufacturing cost.

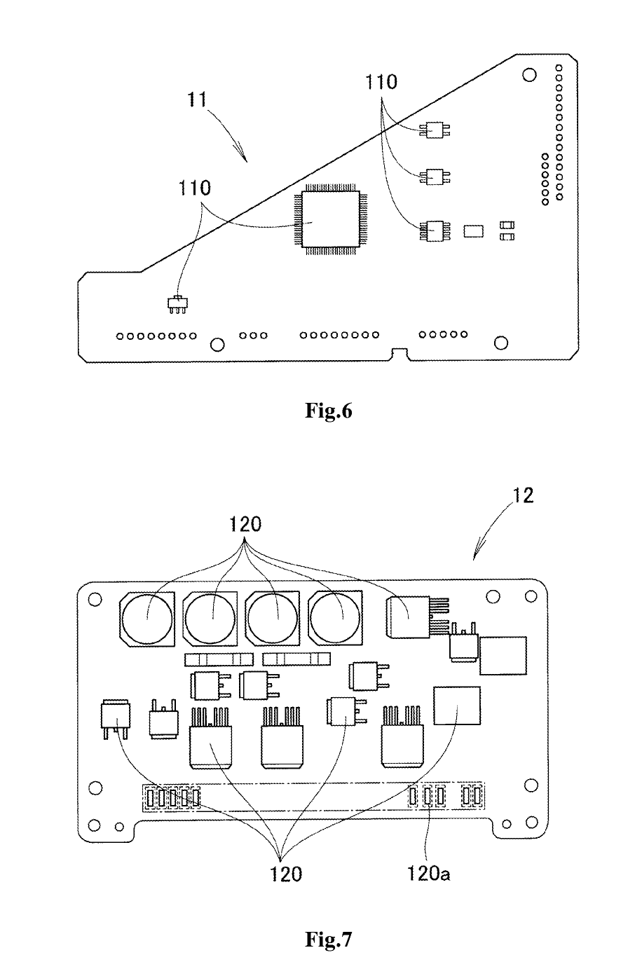

FIG. 6 shows the surface-mounted control components 110 mounted on the control board 11. The surface-mounted control components 110 preferably include a CPU (111 of FIG. 8) that receives a steering torque signal from a torque sensor (70 of FIG. 8) described later and a vehicle velocity signal from a vehicle velocity sensor (80 of FIG. 8) described later, and calculate an assist torque and a driving direction based on these signals, and receive current of the three-phase brushless motor 50 and a feedback signal from an amplifier for an angle sensor (not shown) so as to control driving of a three-phase brushless motor 50. Under the control by the CPU, the control board 11 includes: a drive circuit 112 that drives each of semiconductor switching elements included in a three-phase bridge circuit (121 of FIG. 8); a relay drive circuit 113 that drives a power source relay (125 of FIG. 8) described later; and phase-current detecting circuits 114 (114a to 114c of FIG. 8) that detect respective phase currents with respective shunt resistors (122a to 122c of FIG. 8) connected to corresponding phases.

FIG. 7 shows the surface-mounted power components 120 mounted on the power board 12. The surface-mounted power components 120 preferably include: the semiconductor switching elements (121a to 121f of FIG. 8) included in the three-phase bridge circuit 121; the shunt resistors (122a to 122c of FIG. 8) for phase-current detection provided for respective phases of the three-phase brushless motor; failsafe relays (123a & 123b of FIG. 8); a smoothening electrolytic capacitor (124 of FIG. 8); and a power source relay (125 of FIG. 8). The surface-mounted power components 120 are connected through a portion of the peripheral terminal block 120a disposed on the end portion of the board and a portion of the terminal block 40a insert-molded in the insert molded component 13 to three-phase lines, a power source line, and a signal line of the external three-phase brushless motor, and also to the surface-mounted control components 110 of the control board 11.

FIG. 8 is a block diagram showing a preferred electric circuit configuration of the 1A:ECU and 1B:ECU according to the present preferred embodiment. As shown in FIG. 8, the 1A:ECU and 1B:ECU includes the control board 11 on which the controller (CPU 111), the drive circuit 112, the relay drive circuit 113, and the phase-current detecting circuits 114a to 114c are mounted. The 1A:ECU or 1B:ECU also includes the power board 12 on which the three-phase bridge circuit 121, the shunt resistors 122a to 122c, the failsafe relays 123a, 123b, the electrolytic capacitor 124, and the power source relay 125 are mounted. The torque sensor 70 and the angle sensor 90 are connected to the controller 111 mounted on the control board 11, and the three-phase brushless motor 50 is connected to the three-phase bridge circuit 121 through the failsafe relays 123a, 123b.

The three-phase bridge circuit 121 preferably includes six switching elements TUU (121a), TUL (121b), TVU (121c), TVL (121d), TWU (121e), and TWL (121f), for example. Each of these switching elements TUU (121a), TUL (121b), TVU (121c), TVL (121d), TWU (121e), and TWL (121f) is preferably a MOS-FET (metal oxide semiconductor-field effect transistor) or an IGBT (insulated gate bipolar transistor), for example.

The upper switching element TUU (121a) of the U phase and the lower switching element TUL (121b) of the U phase are connected in series. The upper switching element TVU (121c) of the V phase and the lower switching element TVL (121d) of the V phase are connected in series. The upper switching element TWU (121e) of the W phase and the lower switching element TWL (121f) of the W phase are connected in series. The upper switching elements TUU (121a), TVU (121c), and TWU (121e) of the respective phases are connected through the power source relay 125 to a positive electrode terminal of a battery power source 60. This means that the connecting system of the switching elements TUU (121a) and TUL (121b) of the U phase, the connecting system of the switching elements TVU (121c) and TVL (121d) of the V phase, and the connecting system of the switching elements TWU (121e) and TWL (121f) of the W phase are connected in parallel to one another.

The phase-current detecting circuits 114a to 114c include the respective shunt resistors RSU (122a), RSV (122b), RSW (122c), and signal amplifiers. The lower switching element TUL (121b) of the U phase is connected through the shunt resistor RSU (122a) to the ground. The lower switching element TVL (121d) of the V phase is connected through the shunt resistor RSV (122b) to the ground. The lower switching element TWL (121f) of the W phase is connected through the shunt resistor RSW (122c) to the ground. The phase-current detecting circuits 114 detect respective phase currents flowing in the respective phases U, V, W of the three-phase brushless motor 50 by the corresponding shunt resistors RSU (122a), RSV (122b), RSW (122c), and output the detected values to the controller 111. In other words, each of the phase-current detecting circuits 114a to 114c individually detects the phase current flowing through a line of each phase.

The failsafe relays include the V-phase relay 123a and the W-phase relay 123b. A connecting point between the upper switching element TVU (121c) of the V-phase and the lower switching element TVL (121d) of the V-phase is connected through the V-phase relay 123a to a V-phase coil of the brushless motor 50. A connecting point between the upper switching element TWU (121e) of the W-phase and the lower switching element TWL (121f) of the W-phase is connected through the W-phase relay 123b to a W-phase coil of the brushless motor 50. The failsafe relay may be provided for each phase, but can perform its function if at least two phases are provided with the failsafe relays. The switching elements TUU (121a), TUL (121b), TVU (121c), TVL (121d), TWU (121e), TWL (121f) are individually connected to the corresponding coils U, V, W of the brushless motor 50 via the respective phase wiring.

The electrolytic capacitor 124 is connected in parallel relative to the upper semiconductor switching element and the lower switching element included in the three-phase bridge circuit 121, which are connected in series in each phase, and the electrolytic capacitor 124 is used for the purpose of smoothening. The power source relay 125 is located between the battery power source 60 and the three-phase bridge circuit 121 so as to break current supply for the three-phase bridge circuit 121 under the control by the relay drive circuit 113 through the CPU 111.

The controller 111 preferably includes a microprocessor operated through programs, for example, and controls the drive circuit 112 and the relay drive circuit 113. Based on input signals from the torque sensor 70, the vehicle velocity sensor 80, the angle sensor 90, and the phase-current detecting circuits 114a to 114c, the controller 111 outputs PWM (pulse width modulation) control signals to control the drive circuit 112 as well as control the relay drive circuit 113. The drive circuit 112 switches on or off the switching elements TUU (121a), TUL (121b), TVU (121c), TVL (121d), TWU (121e), TWL (121f) by duty driving. Consequently, the three-phase brushless motor 50 supplied with the current generates an auxiliary torque. The relay drive circuit 113 performs on-off driving on the failsafe relays 123a, 123b and the power source relay 125.

Based on a detected torque value by the torque sensor 70, a detected vehicle velocity value by the vehicle velocity sensor 80, a turning angle value by the angle sensor 90, and detected phase current values by the phase-current detecting circuits 114a to 114c, the controller 111 refers to a target current map recorded on a memory (not shown) so as to calculate an optimum target value to assist the steering force generated by a steering wheel 210. The controller 111 outputs a PWM signal including a duty ratio determined as a current command value based on the above target value to the drive circuit 112, thus drive-controlling each of the switching elements TUU (121a), TUL (121b), TVU (121c), TVL (121d), TWU (121e), TWL (121f).

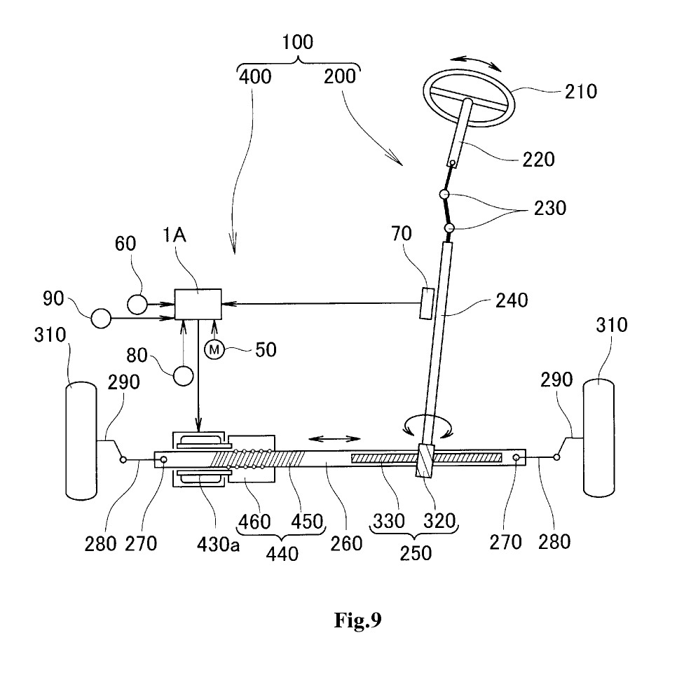

The 1A:ECU and 1B:ECU according to the present preferred embodiment (corresponding to 1A in FIG. 9) is preferably mounted on the EPS 100 for the purpose of control. FIG. 9 schematically shows a structural outline of the EPS. The EPS 100 preferably includes a steering system 200 from the steering wheel 210 to steerable wheels (e.g., front wheels) 310 of the vehicle, and an assist torque mechanism 400 that applies an auxiliary torque to this steering system 200.

The steering system 200 preferably includes: the steering wheel 210; a pinion shaft 240 connected to the steering wheel 210 through a steering shaft 220 and universal joints 230; a rack shaft 260 connected to the pinion shaft 240 through a rack and pinion mechanism 250; and the right and left steerable wheels 310 coupled to both ends of the rack shaft 260 through ball joints 270, tie rods 280, and knuckles 290. The rack and pinion mechanism 250 includes a pinion 320 provided on the pinion shaft 240, and a rack 330 provided on the rack shaft 260. According to the steering system 200, the driver steers the steering wheel 210 to steer the right and left steerable wheels 310 with the generated steering torque through the rack and pinion mechanism 250, the rack shaft 260, and the right and left tie rods 280.

The assist torque mechanism 400 preferably includes: the torque sensor 70; the three-phase brushless motor 50; the torque transmission mechanism 440; the 1A:ECU or 1B:ECU as a brushless motor controller; the vehicle velocity sensor 80; and the angle sensor 90. The torque sensor 70 detects a steering torque of the steering system 200 applied to the steering wheel 210. The vehicle velocity sensor 80 detects a vehicle velocity. The angle sensor 90 detects a turning angle of the three-phase brushless motor 50. The torque transmission mechanism 440 is preferably defined by a ball screw, for example.

As described above, the assist torque mechanism 400 is configured to generate a control signal in the 1A:ECU or 1B:ECU based on the steering torque detected by the torque sensor 70, generate an auxiliary torque (motor torque) corresponding to the steering torque in the three-phase brushless motor 50 based on the generated control signal, and transmits the auxiliary torque to the rack shaft 260 via the torque transmission mechanism 440. More specifically, the 1A:ECU or 1B:ECU generates the control signal based on the vehicle velocity detected by the vehicle velocity sensor 80, and the turning angle of the three-phase brushless motor 50 detected by the angle sensor 90 in addition to the steering torque.

A motor shaft 430a of the three-phase brushless motor 50 is preferably a hollow shaft covering the rack shaft 260. The torque transmission mechanism 440 includes: a screw portion 450 located at a portion of the rack shaft 260 excluding the rack 330; a nut 460 assembled to the screw portion 450; and multiple balls. The nut 460 is coupled to the motor shaft 430a. The torque transmission mechanism may be configured to transmit the auxiliary torque generated by the three-phase brushless motor 50 directly to the pinion shaft 240.

The EPS 100 including the 1A:ECU or 1B:ECU according to the present preferred embodiment is capable of steering the steerable wheels 310 with a so-called “complex torque” obtained by adding the auxiliary torque generated by the three-phase brushless motor 50 to the steering torque transmitted from the steering wheel 210 to the rack shaft 260.

As described above, according to the 1A:ECU or 1B:ECU of the present preferred embodiment, it is preferred that the control circuit, which is to be mounted on the control board 11 (first board) herein, for example, and the power circuits, which are to be mounted on the power board 12 (second board) herein, for example, are mounted on their own dedicated boards, thus attaining efficient layout without deviation of the electronic components, thus downsizing the entire electronic controller for the electric power steering. By mounting the power circuits together on the second board, it is possible to eliminate redundant connections as well as attain efficient wiring. In addition, all the electronic components required as the 1A:ECU or 1B:ECU are preferably surface-mounted, thus achieving reduction in thickness, and the insert molded component 13 is connected through the reflow soldering which is the same process as that used for the electronic components, thus simplifying the manufacturing process of the ECU assembly to simplify the assembly process, thus attaining reduction in cost.

The insert molded component 13 is preferably arranged in line at the connecting portion between the control board 11 and the power board 12, thus eliminating wiring to the connectors located apart because of limitation of the mounting positions of the components, which results in simplified wiring layout and enhanced flexibility of the wiring design. The flexibility of the layout of the second surface-mounted components is also enhanced, so that it is possible to maximize the effective mounting area for the components on the second board, thus downsizing the 1A:ECU or 1B:ECU. The insert molded component 13 is configured not to be in a rectangular shape, but to be in an L-shape, thus downsizing and simplifying the component to reduce the manufacturing cost. In the case of changing the mounting position of the 1A:ECU or 1B:ECU, of the insert molded component 13, only a portion affected by influences due to this change is remade, thus reducing cost required for changing the mold, thus attaining reduction in cost for the 1A:ECU or 1B:ECU.

Furthermore, the 1A:ECU or 1B:ECU according to the present preferred embodiment is preferably configured to hold the insert molded connectors between the protective cover 10 and the heat sink 20, so that heat generated from the mounted components having a high current capacity that are mounted on the power board 12 is externally radiated through the power board 12 and the heat sink 20 made of metallic material having a high heat radiation, for example; therefore, the heat is efficiently radiated to the outside, which enhances cooling effect, thus providing the highly reliable electronic controller for electric power steering. The electronic components having a relatively high current capacity, such as the electrolytic capacitors at least one of which is provided for each pair of the semiconductor switching elements of each phase of the three-phase bridge circuit, and the failsafe relays 123a, 123b configured to break the driving current to be supplied to a corresponding phase of the three-phase brushless motor 50, in the case of having an abnormality in the driving current flowing in any one of the phases, are surface-mounted on the power board 12, thus attaining reduction in thickness, and allowing all the components to be connectable through reflow soldering, thus simplifying the assembly process, and resulting in cost reduction.

Features of the above-described preferred embodiments and the modifications thereof may be combined appropriately as long as no conflict arises.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic controller for electric power steering, comprising:
a first board;
a second board;
an insert molded component;
a heat sink; and
a protective cover; wherein
first surface-mounted components are mounted on the first board;
second surface-mounted components having a higher tolerant current capacity than that of the first surface-mounted components are mounted on the second board;
the insert molded component includes connectors mounted at a first end portion of the second board and mounted at a second end portion located vertically to the first end portion;
the heat sink radiates heat transferred from the second surface-mounted components to the second board; and
the protective cover is fixed to the heat sink to cover the first board and the second board on which the insert molded component is mounted.

2. The electronic controller for electric power steering according to claim 1, wherein
the insert molded component includes:
a first portion mounted at the first end portion of the second board; and
a second portion mounted at the second end portion of the second board;
the first portion includes a first connector;
the second portion includes a second connector and a third connector; and
each of the first portion and the second portion includes a coupling portion.

3. The electronic controller for electric power steering according to claim 2, wherein
the first connector having a first shape or a second shape to be determined depending on a layout of a vehicle is selectively mounted at the first portion of the insert molded component.

4. The electronic controller for electric power steering according to claim 2, wherein
a power source is connected to the second connector of the insert molded component;
a vehicle sensor that detects a vehicle state is connected to the third connector of the insert molded component; and
a three-phase brushless motor that assists steering of the vehicle is connected to the first connector of the insert molded component.

5. The electronic controller for electric power steering according to claim 3, wherein
a power source is connected to the second connector of the insert molded component;
a vehicle sensor that is configured to detect a vehicle state is connected to the third connector of the insert molded component; and
a three-phase brushless motor that is configured to assist steering of the vehicle is connected to the first connector of the insert molded component.

6. The electronic controller for electric power steering according to claim 2, wherein
the first connector of the insert molded component includes a first wall portion in contact with an inside portion of a slit in a longitudinal side wall of the protective cover;
the second connector of the insert molded component includes a second wall portion in contact with an inside portion of a cutout in a side wall located vertically to the longitudinal direction of the protective cover; and
the third connector of the insert molded component includes a third wall portion in contact with another inside portion of the cutout in the side wall located vertically to the longitudinal direction of the protective cover.

7. The electronic controller for electric power steering according to claim 3, wherein
the first connector of the insert molded component includes a first wall portion in contact with an inside portion of a slit in a longitudinal side wall of the protective cover;
the second connector of the insert molded component includes a second wall portion in contact with an inside portion of a cutout in a side wall located vertically to the longitudinal direction of the protective cover; and
the third connector of the insert molded component includes a third wall portion in contact with another inside portion of the cutout in the side wall located vertically to the longitudinal direction of the protective cover.

8. The electronic controller for electric power steering according to claim 4, wherein
the first connector of the insert molded component includes a first wall portion in contact with an inside portion of a slit in a longitudinal side wall of the protective cover;
the second connector of the insert molded component includes a second wall portion in contact with an inside portion of a cutout in a side wall located vertically to the longitudinal direction of the protective cover; and
the third connector of the insert molded component includes a third wall portion in contact with another inside portion of the cutout in the side wall located vertically to the longitudinal direction of the protective cover.

9. The electronic controller for electric power steering according to claim 1, wherein
the insert molded component includes an insert molded terminal block mounted in line along the first end portion or the second end portion of the second board to connect the first surface-mounted components to the second surface-mounted components.

10. The electronic controller for electric power steering according to claim 2, wherein
the insert molded component includes an insert molded terminal block mounted in line along the first end portion or the second end portion of the second board to connect the first surface-mounted components to the second surface-mounted components.

11. The electronic controller for electric power steering according to claim 3, wherein
the insert molded component includes an insert molded terminal block mounted in line along the first end portion or the second end portion of the second board to connect the first surface-mounted components to the second surface-mounted components.

12. The electronic controller for electric power steering according to claim 4, wherein
the insert molded component includes an insert molded terminal block mounted in line along the first end portion or the second end portion of the second board as connect the first surface-mounted components to the second surface-mounted components.

13. The electronic controller for electric power steering according to claim 6, wherein
the insert molded component includes an insert molded terminal block mounted in line along the first end portion or the second end portion of the second board to connect the first surface-mounted components to the second surface-mounted components.

14. The electronic controller for electric power steering according to claim 1, wherein
the first board includes a board having a smaller area than that of the second board, and including a first side mounted to oppose the first end portion of the insert molded component, and a second side mounted to oppose the second end portion of the insert molded component.

15. The electronic controller for electric power steering according to claim 1, wherein
the first surface-mounted components include:
a controller that is configured and/or programmed to perform duty-driving on semiconductor switching elements that supply driving current for respective phases of a three-phase brushless motor based on a steering force of a steering system detected by an external torque sensor to perform a steering assist control by using the three-phase brushless motor; and
the second surface-mounted components include:
a three-phase bridge circuit including a pair of the semiconductor switching elements provided for each phase of the three-phase brushless motor to supply each phase with the driving current determined by the duty driving;
at least one electrolytic capacitor which is provided for each pair of the semiconductor switching elements so as to absorb ripples in the driving current;
current detecting circuits each of which is individually connected between the three-phase brushless motor and each pair of the semiconductor switching elements included in the three-phase bridge circuit so as to detect driving current flowing in each phase;
failsafe relays configured, in a case of having an abnormality in the driving current in any one of the phases, to break the driving current to be supplied for a corresponding phase of the three-phase brushless motor; and
a power source relay disposed between a battery power source and the three-phase bridge circuit to break current to be supplied for the three-phase bridge circuit.

16. The electronic controller for electric power steering according to claim 2, wherein
the first surface-mounted components include:
a controller that is configured and/or programmed to perform duty-driving on semiconductor switching elements that supply driving current for respective phases of a three-phase brushless motor based on a steering force of a steering system detected by an external torque sensor to perform a steering assist control by using the three-phase brushless motor; and
the second surface-mounted components include:
a three-phase bridge circuit including a pair of the semiconductor switching elements provided for each phase of the three-phase brushless motor to supply each phase with the driving current determined by the duty driving;
at least one electrolytic capacitor which is provided for each pair of the semiconductor switching elements so as to absorb ripples in the driving current;
current detecting circuits each of which is individually connected between the three-phase brushless motor and each pair of the semiconductor switching elements included in the three-phase bridge circuit so as to detect driving current flowing in each phase;
failsafe relays configured, in a case of having an abnormality in the driving current in any one of the phases, to break the driving current to be supplied for a corresponding phase of the three-phase brushless motor; and
a power source relay disposed between a battery power source and the three-phase bridge circuit to break current to be supplied for the three-phase bridge circuit.

17. The electronic controller for electric power steering according to claim 3, wherein
the first surface-mounted components include:
a controller that is configured and/or programmed to perform duty-driving on semiconductor switching elements that supply driving current for respective phases of a three-phase brushless motor based on a steering force of a steering system detected by an external torque sensor to perform a steering assist control by using the three-phase brushless motor; and
the second surface-mounted components include:
a three-phase bridge circuit including a pair of the semiconductor switching elements provided for each phase of the three-phase brushless motor to supply each phase with the driving current determined by the duty driving;
at least one electrolytic capacitor which is provided for each pair of the semiconductor switching elements so as to absorb ripples in the driving current;
current detecting circuits each of which is individually connected between the three-phase brushless motor and each pair of the semiconductor switching elements included in the three-phase bridge circuit so as to detect driving current flowing in each phase;
failsafe relays configured, in a case of having an abnormality in the driving current in any one of the phases, to break the driving current to be supplied for a corresponding phase of the three-phase brushless motor; and
a power source relay disposed between a battery power source and the three-phase bridge circuit to break current to be supplied for the three-phase bridge circuit.

18. The electronic controller for electric power steering according to claim 4, wherein
the first surface-mounted components include:
a controller that is configured and/or programmed to perform duty-driving on semiconductor switching elements that supply driving current for respective phases of a three-phase brushless motor based on a steering force of a steering system detected by an external torque sensor to perform a steering assist control by using the three-phase brushless motor; and
the second surface-mounted components include:
a three-phase bridge circuit including a pair of the semiconductor switching elements provided for each phase of the three-phase brushless motor to supply each phase with the driving current determined by the duty driving;
at least one electrolytic capacitor which is provided for each pair of the semiconductor switching elements so as to absorb ripples in the driving current;
current detecting circuits each of which is individually connected between the three-phase brushless motor and each pair of the semiconductor switching elements included in the three-phase bridge circuit so as to detect driving current flowing in each phase;
failsafe relays configured, in a case of having an abnormality in the driving current in any one of the phases, to break the driving current to be supplied for a corresponding phase of the three-phase brushless motor; and
a power source relay disposed between a battery power source and the three-phase bridge circuit to break current to be supplied for the three-phase bridge circuit.

19. The electronic controller for electric power steering according to claim 9, wherein
the first surface-mounted components include:
a controller that is configured and/or programmed to perform duty-driving on semiconductor switching elements that supply driving current for respective phases of a three-phase brushless motor based on a steering force of a steering system detected by an external torque sensor to perform a steering assist control by using the three-phase brushless motor; and
the second surface-mounted components include:
a three-phase bridge circuit including a pair of the semiconductor switching elements provided for each phase of the three-phase brushless motor to supply each phase with the driving current determined by the duty driving;
at least one electrolytic capacitor which is provided for each pair of the semiconductor switching elements so as to absorb ripples in the driving current;
current detecting circuits each of which is individually connected between the three-phase brushless motor and each pair of the semiconductor switching elements included in the three-phase bridge circuit so as to detect driving current flowing in each phase;
failsafe relays configured, in a case of having an abnormality in the driving current in any one of the phases, to break the driving current to be supplied for a corresponding phase of the three-phase brushless motor; and
a power source relay disposed between a battery power source and the three-phase bridge circuit to break current to be supplied for the three-phase bridge circuit.

20. The electronic controller for electric power steering according to claim 14, wherein
the first surface-mounted components include:
a controller that is configured and/or programmed to perform duty-driving on semiconductor switching elements that supply driving current for respective phases of a three-phase brushless motor based on a steering force of a steering system detected by an external torque sensor to perform a steering assist control by using the three-phase brushless motor; and
the second surface-mounted components include:
a three-phase bridge circuit including a pair of the semiconductor switching elements provided for each phase of the three-phase brushless motor to supply each phase with the driving current determined by the duty driving;
at least one electrolytic capacitor which is provided for each pair of the semiconductor switching elements so as to absorb ripples in the driving current;
current detecting circuits each of which is individually connected between the three-phase brushless motor and each pair of the semiconductor switching elements included in the three-phase bridge circuit so as to detect driving current flowing in each phase;
failsafe relays configured, in a case of having an abnormality in the driving current in any one of the phases, to break the driving current to be supplied for a corresponding phase of the three-phase brushless motor; and
a power source relay disposed between a battery power source and the three-phase bridge circuit to break current to be supplied for the three-phase bridge circuit.
